(19) United States
(12) Patent Application Publication
(10) Pub. No.: US 2005/0184798 A1
(43) Pub. Date: Aug. 25, 2005

(54) Comparator

(76) Inventors: Nobumasa Higemoto, Kanagawa (JP); Shuichi Matsumoto, Tokyo (JP); Akira Horikawa, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/053,955

(22) Filed: Feb. 10, 2005

(30) Foreign Application Priority Data
Feb. 20, 2004 (JP) 2004-044105

(51) Int. Cl. H03K 5/153

(52) U.S. Cl. 327/543

(57) ABSTRACT

A comparator is constructed to exclude an adverse effect of variation of a power source potential VDD or the like on a current output Iout. The comparator comprises a first voltage follower portion which receives an input potential Vin and outputs a potential (=Vin) following the input potential, a second voltage follower portion which receives a reference voltage Vref and outputs a potential (=Vref) following the input potential, and a current subtracting portion which outputs as a comparison result (Iout) a value achieved by subtracting the amount of current flowing due to the potential difference between the power source potential VDD of the comparator and the output potential (=Vref) of the second voltage follower portion from the amount of current flowing due to the potential difference between the power source potential VDD of the comparator and the output potential (=Vin) of the first voltage follower portion.

### BACKGROUND OF THE INVENTION

1. Field of the Invention

The present invention relates to a comparator used for a receiver signal strength indicator (RSSI) in mobile communication, etc.

2. Description of the Related Art

In transmission/reception control of a transceiver in mobile communication, it is one of remarkable important measurement items to measure whether the receiver signal strength of a received signal satisfies a predetermined level range. The measurement as to whether the receiver signal strength satisfies the predetermined level range is carried out by comparing the potential of a reception signal received by a transceiver and the potential of a reference signal generated by a reference signal generating circuit installed in the transceiver with a comparator. An example of the comparator will be described hereunder.

FIG. 1 is a diagram showing the construction of a conventional comparator.

The conventional comparator is constituted with a differential amplifier circuit comprising NMOS type FET; MN101, NMOS type FET; MN102 and NMOS type FET; MN103. As shown in FIG. 1, a power source potential VDD is applied to the drain of the MNOS type FET; MN101 through PMOS type FET; MP100 serving as a protection circuit, and the source of the NMOS type FET; MN101 and the source of the NMOS type FET; MN102 are connected to the drain of the NMOS type FET; MN103 serving as a constant current source. The source of NMOS type FET; MN103 is grounded.

In this comparator, an input potential Vin applied to the gate of the NMOS type FET; MN101 is compared with a reference potential Vref applied to the gate of the NMOS type FET; MN102, and the comparison result is output as a current output Iout from the drain of the NMOS type FET; MN102.

Here, the input potential Vin corresponds to the potential of a signal received by the transceiver, and the reference potential Vref corresponds to the potential of the reference signal generated by a level generating circuit installed in the transceiver. The current output Iout is a value achieved by converting the potential difference between the input potential Vin and the reference potential Vref to a current amount.

On the basis of the operation principle of the differential amplifier shown in FIG. 1, the sum of the current amount I1 flowing in the NMOS type FET; MN101 and the current amount I2 flowing in the NMOS type FET; MN102 is equal to the current amount I0 (I1+I2=I0) flowing in the NMOS type FET; MN103, and the current amount I0 is a constant current amount. As shown in FIG. 1, the current amount I2 flowing in the NMOS type FET; MN102 is equal to the current output Iout, and the power source potential applied to the differential amplifier circuit is equal to VDD, and a predetermined bias potential BIAS is applied to the gate of the NMOS type FET; MN103.

As described above, according to the conventional comparator, when the relationship between the input potential Vin and the reference potential Vref satisfies Vin<Vref, the relationship between the current amount I1 flowing in the NMOS type FET; MN101 and the current amount I2 flowing in the NMOStype FET; MN102 satisfies I1<I2, and the Iout=I2>I0/2. Conversely, when the relationship between the input potential Vin and the reference potential Vref satisfies Vin>Vref, the relationship between the current amount I1 flowing in the NMOS type FET; MN101 and the current amount I2 flowing in the NMOS type FET; MN102 satisfies I1>I2, and thus the Iout=I2<I0/2. Accordingly, the comparison result of the input potential Vin and the reference potential Vref can be known by monitoring the current amount of the current output Iout.

However, in the conventional comparator, variation of the power source potential VDD or variation of the bias potential BIAS causes variation of the current amount I1, and thus there is liable to occur a case where the drain/source potential difference Vds for operating the NMOS type FET; MN103 in a saturation region cannot be secured. As a result, the NMOS type FET; MN103 operates in a non-saturation region, and thus the current value of the current amount I0 flowing in the NMOS type FET; MN103 serving as a constant current source is reduced to a smaller value than that when the NMOS type FET; MN103 operates in the saturation region. That is, the variation of the power source potential VDD or the variation of the bias potential BIAS causes the variation of the current output Iout, and thus it adversely affects the comparison result.

As described above, the influence of the variation of the power source potential VDD or the variation of the bias potential BIAS on the characteristic of the conventional comparator cannot be neglected. Therefore, there have been various countermeasure methods for a case where the variation of the power source potential VDD or the variation of the bias potential BIAS occurs due to thermal noise or the like.

For example, Japanese Patent Kokai No. 2002-26700 (Patent Document 1) discloses one of these countermeasure methods.

The problem to be solved by the present invention resides in that the variation of the power source potential VDD or the variation of the bias potential BIAS causes the variation of the current output Iout and thus adversely affects on the comparison result in the conventional comparator.

### SUMMARY OF THE INVENTION

In order to attain the above object, according to the present invention, there is provided a comparator equipped with a first voltage follower portion which receives an input potential Vin corresponding to a signal to be compared and comprises a voltage follower circuit, a second voltage follower portion which receives a reference potential Vref serving as a reference signal and comprises a voltage follower circuit, and a current subtracting portion for outputting as a comparison result a value achieved by subtracting the amount of current flowing owning to the potential difference between the power source potential of the comparator and the output potential of the second voltage follower portion from the amount of current flowing due to the potential difference between the power source potential of the comparator and the output potential of the first voltage follower portion.

According to the comparator of the present invention, the input potential Vin is received through the first voltage follower circuit, and the reference potential Vref is received through the second voltage follower circuit. Accordingly, the output potential thereof is hardly affected by the variation of the power source potential VDD or the like. Therefore, even when the power source potential VDD varies, the output potential of the first voltage follower circuit is equal to the input potential Vin, and the output potential of the second voltage follower circuit is equal to the reference potential Vref. Furthermore, since the value achieved by subtracting the amount of current (VDD−Vref)/R2 flowing due to the potential difference between the power source potential of the comparator and the output potential of the second voltage follower portion from the amount of current (VDD-Vin)/R1 flowing owning to the potential difference between the power source potential VDD of the comparator and the output potential of the first voltage follower portion is output as the comparison result, the output current amount is independent of VDD under the condition that R1=R2. Accordingly, even when the power source potential VDD or the bias potential BIAS varies, the variation of the output potential can be suppressed, and the influence on the comparison result can be suppressed.

The first voltage follower portion is constructed by using an operational amplifier which receives a potential to be compared from a minus polarity terminal and feeds back the output potential thereof to a plus polarity terminal while inverting the polarity of the output potential, and the second voltage follower portion is constructed by using an operational amplifier which receives a reference potential from the minus polarity terminal and feeds back the output potential thereof to the plus polarity terminal while inverting the polarity of the output potential, whereby increase of the number of parts can be minimized.

### BRIEF DESCRIPTION OF THE DRAWINGS

FIG. 1 is a diagram showing the construction of a conventional comparator;

FIG. 2 is a diagram showing the circuit construction of a comparator according to the present invention;

FIG. 3 is a diagram showing a voltage follower circuit; and

FIG. 4 is a diagram showing the voltage follower circuit.

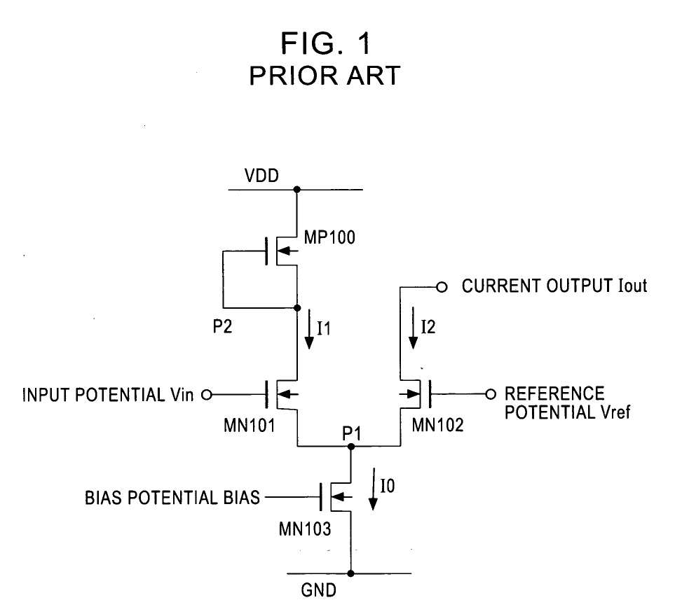

### DETAILED DESCRIPTION OF THE PREFERRED EMBODIMENT

A preferred embodiment according to the present invention will be described hereunder with reference to the accompanying drawings.

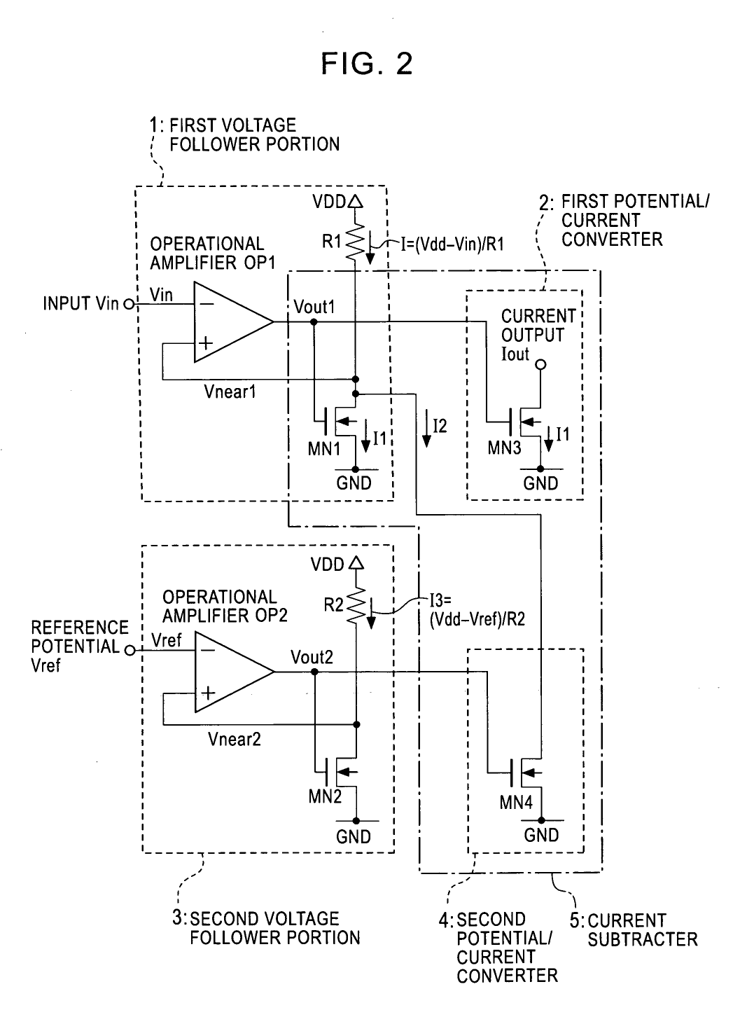

FIG. 2 is a diagram showing the circuit construction of a comparator according to the present invention.

As shown in FIG. 2, the comparator of the present invention comprises a first voltage follower portion 1, a first potential/current converter 2, a second voltage follower portion 3, a second potential/current converter 4 and a current subtracter 5.

The first voltage follower portion 1 receives a comparison potential to be compared, and applies an output potential substantially equal to the comparison potential to the first potential/current converter 2. It contains a voltage follower circuit. The voltage follower circuit will be described.

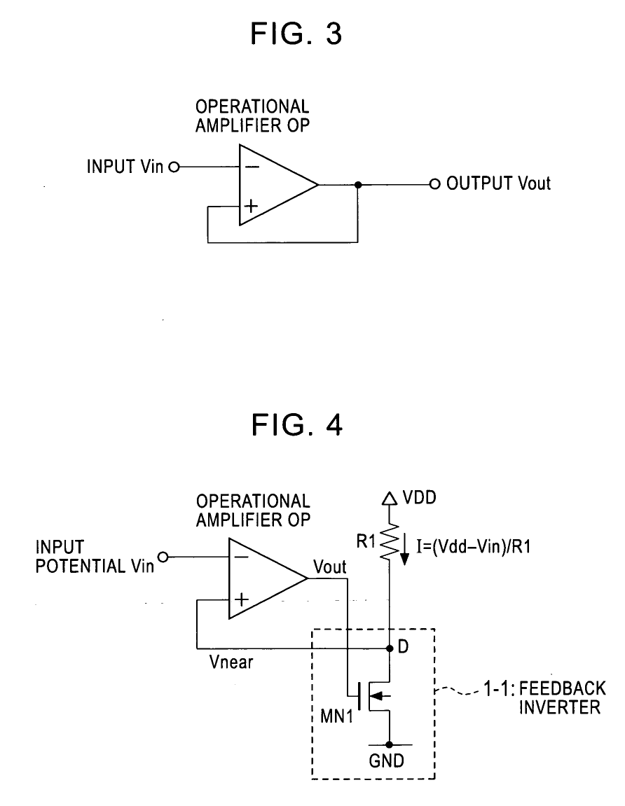

FIGS. 3 and 4 are diagrams showing the voltage follower circuit. Specifically, FIG. 3 is a diagram showing the basic circuit construction of the voltage follower circuit, and FIG. 4 is a diagram showing the circuit construction of the voltage follower circuit used in the present invention.

In the basic circuit construction of the voltage follower circuit, as shown in FIG. 3, an input potential Vin is input to the plus (+) terminal of an operational amplifier OP, and the output potential Vout of the operational amplifier OP is fed back to the minus (−) terminal thereof. With this construction, the potential difference between the potential at the (+) terminal and the potential at the (0) terminal is equal to zero, and the amplification factor of the voltage follower circuit is equal to 1, so that the output potential Vout follows the input potential Vin (Vin=Vout). In the voltage follower circuit, the amplification factor of the operational amplifier OP is remarkably large, and thus an unsaturated zone is narrowed, so that the relation of Vin=Vout is liable to be kept irrespective of variation of the power source potential.

In the voltage follower circuit (FIG. 4) used in the present invention, the input potential Vin is input to the (−) terminal of the operational amplifier OP, and the output potential Vout of the operational amplifier OP is supplied to the gate terminal of an NMOS type FET; MN 1. The drain terminal of the NMOS type FET; MN 1 is connected to the power source potential VDD through a resistor R1, the source terminal thereof is grounded, and a drain current amount I (=(Vdd−Vnear)/R1) flows between the drain terminal and the source terminal.

The output potential Vout is inverted in polarity by a feedback inverter 1-1 (NMOS type FET; MN1), and it appears as a drain potential Vnear at the drain terminal. This drain potential Vnear is fed back to the (+) terminal of the operational amplifier OP.

Here, increase of the input potential Vin causes reduction of the output potential Vout, and the reduction of the output potential Vout causes increase of the drain potential Vnear. Therefore, the increase/decrease of the potential at the (+) terminal of the operational amplifier OP follows the increase/decrease of the potential at the (−) terminal of the operation amplifier OP. As a result, the circuit shown in FIG. 4 constitutes a voltage follower circuit by setting Vdd and R1 to predetermined values in the drain current amount I=(Vdd−Vnear)/R1 of the NMOS type FET; MN1. In this case, Vnear=Vout=Vin, and thus the drain current amount I of the NMOS type FET; MN1 is equal to (Vdd-Vin)/R1.

Referring to FIG. 2 again, the first voltage follower portion 1 receives the comparison potential to be compared (input Vin) and supplies the first potential/current converter 2 with the output potential Vout1 which is substantially equal to the comparison potential (input Vin).

As in the case of the voltage follower circuit shown in FIG. 4, the first voltage follower portion 1 receives an input potential Vin at the (−) terminal of an operational amplifier OP1 and supplies the output potential Vout1 thereof to the gate terminal of the NMOS type FET; MN1. The drain terminal of the NMOS type FET; MN1 is connected to the power source potential VDD through the resistor R1, and the source terminal thereof is grounded. Accordingly, the current amount I flowing through the resistor R1 is represented by the following equation 1:
I=((Vdd−Vin)/R1) (equation 1)

This current amount I is equal to the sum of the drain current amount I1 of the NMOS type FET; MN1 and the current amount I2 which is shared to the second potential/current converter 4 because the current subtracter 5 described later is constructed, and thus the drain current amount I1 is represented by the following equation 2:
I1=((Vdd−Vin)/R1)−I2 (equation 2)

Furthermore, the output potential Vout1 of the first voltage follower portion 1 is supplied to the first potential/current converter 2.

The first potential/current converter 2 converts the output potential of the first voltage follower portion 1 to a current amount, and it comprises an NMOS type FET; MN3. The gate terminal of the NMOS type FET; MN3 is supplied with the output potential Vout1 of the first voltage follower portion 1, the drain terminal thereof is connected to the output terminal of the comparator, and the source terminal thereof is grounded. Since the gate terminal is supplied with the output potential Vout1 of the first voltage follower portion 1, the drain current amount of the NMOS type FET; MN3 is equal to the drain current amount I1=((Vdd−Vin)/R1)−I2 of the NMOS type FET; MN1 which is represented by the equation 2.

The second voltage follower portion 3 receives the reference potential Vref, and supplies the output potential equal to the reference potential Vref to the second potential/current converter 4.

As in the case of the voltage follower circuit shown in FIG. 4, the second voltage follower portion 3 receives the reference potential Vref at the (−) terminal of the operational amplifier OP2, and supplies the output potential Vout2 thereof to the gate terminal of the NMOS type FET;MN2. The drain terminal of the NMOS type FET; MN2 is connected to the power source potential VDD through a resistor R2, and the source terminal thereof is grounded. Accordingly, the drain current amount I3 flowing between the drain terminal and the source terminal is represented by the following equation 3:
I3=((Vdd−Vref)/R2) (equation 3)
Furthermore, the output potential Vout2 of the second voltage follower portion 3 is supplied to the second potential/current converter 4.

The second potential/current converter 4 converts the output potential of the second voltage follower portion 3 to the current amount, and it comprises an NMOS type FET; MN4. The gate terminal thereof is supplied with the output potential Vout2 of the second voltage follower portion 3, the drain terminal thereof is connected to the drain of the NMOS type FET; MN1 because the current subtracter 5 described later is constructed, and the source terminal thereof is grounded. Since the gate terminal is supplied with the output potential Vout of the second voltage follower portion 3, the drain current amount of the NMOS type FET; MN4 is equal to the drain current amount I3=((Vdd−Vref)/R2) of the NMOS type FET; MN2 represented by the equation 3. Furthermore, the drain current amount I3 of the NMOS type FET; MN2 is equal to I2 because the current subtracter 5 described later is constructed.

The current subtracter 5 outputs as a comparison result (current output Iout) a value achieved by subtracting the current amount I3 (VDD-Vref)/R2 flowing due to the potential difference between the power source potential VDD of the comparator and the output potential (=Vref) of the second voltage follower portion 3 from the current amount I=(VDD−Vin)/R1 flowing due to the potential difference between the power source potential VDD of the comparator and the output potential (=Vin) of the first voltage follower portion 1.

The current subtracter 5 is necessarily constructed by connecting the drain terminal of the NMOS type FET; MN1 and the drain terminal of the NMOS type FET;MN4. By constructing the current subtracter 5, the current amount I3 flowing in the second potential/current converter 4 is equal to I2, and
I=I1+I3 (equation 4)

Accordingly, from the above-described equations 1 to 4, i.e., I=(Vdd−Vin)/R1 (equation 1), I1=((Vdd−Vin)/R1)−I2 (equation 2), I3=((Vdd−Vref)/R2) (equation 3) and I=I1+I3 (equation 4), the following equation is achieved:
I1=((Vdd−Vin)/R1)−((Vdd−Vref)/R2) (equation 5)

In the above equation 5, when R1=R2,
I1=(Vref−Vin)/R1 (equation 6)

The I1 of the equation 6 is equal to Iout which is the output of the first potential/current converter 2. From the equation 6, it is apparent that the current output Iout of the comparator of the present invention is free from the variation of the power source VDD or the bias potential BIAS.

That is, according to the present invention, the input potential Vin and the reference potential Vref are received through the voltage follower circuit, and thus the output thereof is hardly influenced by the variation of the power source potential VDD or the variation of the bias potential BIAS, so that even when the power source potential VDD or the bias potential BIAS varies, the variation of the output is suppressed and thus the influence on the comparison result is suppressed.

The foregoing description is described by applying the comparator of the present invention to the receiver signal strength indicator (RSSI) in mobile communication, and thus the two signals to be compared with each other are limited to the input potential Vin and the reference potential Vref. However, the present invention is not limited to this mode. That is, one of the two signals to be compared is not limited to the reference potential, and both the potentials may be varied.

This application is based on Japanese Patent Application No. 2004-044105 which is herein incorporated by reference.

1. A comparator for receiving two signals, converting the potential difference between the two signals to a current amount and outputting the current amount as a comparison result of the two signals, comprising:
a first voltage follower portion for receiving any one of the two signals and outputting a potential following the input potential of the one signal;
a second voltage follower portion for receiving the other signal of the two signals and outputting a potential following the input potential of the other signal; and
a current subtracter for outputting as the comparison result a value achieved by subtracting the amount of current flowing due to the potential difference between the power source potential of the comparator and the output potential of the second voltage follower portion from the amount of current flowing due to the potential difference between the power source potential of the comparator and the output potential of the first voltage follower portion.

2. The comparator according to claim 1, wherein a resistance value for setting the current amount flowing due to the potential difference between the power source potential of the comparator and the output potential of the first voltage follower portion is equal to a resistance value for setting the current amount flowing due to the potential difference between the power source potential of the comparator and the output potential of the second voltage follower portion.

3. The comparator according to claim 1, wherein the first voltage follower portion is equipped with an operational amplifier having a minus polarity terminal for receiving a comparison potential to be compared and a plus polarity terminal for receiving a feedback potential, and a feedback inverter for inverting the polarity of the output of the operational amplifier and outputting the polarity-inverted output of the operational amplifier to the plus polarity terminal, and the second voltage follower portion is equipped with an operational amplifier having a minus polarity terminal for receiving a reference potential and a plus polarity terminal for receiving a feedback potential, and a feedback inverter for inverting the polarity of the output of the operational amplifier, and outputting the polarity-inverted output of the operational amplifier to the plus polarity terminal.
